(19) United States
(12) Patent Application Publication
(10) Pub. No.: US 2021/0082969 A1
(43) Pub. Date: Mar. 18, 2021

(54) ARRAY SUBSTRATE AND METHOD OF MANUFACTURING THE SAME

(71) Applicant: HKC Corporation Limited, Shenzhen, Guangdong (CN)

(72) Inventor: Huai Liang HE, Chongqing (CN)

(21) Appl. No.: 16/650,248

(22) PCT Filed: Dec. 12, 2017
(86) PCT No.: PCT/CN2017/115602

§ 371 Date: Mar. 24, 2020

(30) Foreign Application Priority Data
Sep. 25, 2017 (CN) 201710876476.5

(51) Int. Cl. H01L 27/12; H01L 27/146

(52) U.S. Cl. CPC H01L 27/1233; H01L 27/14698; H01L 27/14607; H01L 27/1288

(57) ABSTRACT

An array substrate and manufacturing method thereof are provided. The method includes: forming a gate metal layer on a substrate, and forming a gate insulating layer on the gate metal layer; forming amorphous silicon layer, N-type amorphous silicon layer, source and drain metals on the gate insulating layer corresponding to the gate metal layer, the source and drain metals being on same layer; forming a metal layer to be a lower metal layer of photosensor on an extension of the gate insulating layer; forming light sensing layer, passivation layer and photoresist layer on source metal, drain metal and metal layer; and forming the first light sensing layer and first passivation layer on the source and drain metals to form switch element; and forming the second light sensing layer and second passivation layer on the metal layer to form the photosensor by etching with same halftone mask.

### BACKGROUND

### Technology Field

This disclosure relates to a technical field of a display, and more particularly to an array substrate and a method of manufacturing the same.

### Description of Related Art

The display has many advantages, such as the slim body, the power-saving property, the radiation less property and the like, and has been widely used. Most of the displays in the existing market are backlight displays, which include a display panel and a backlight module. The working principle of the display panel is to refract the light rays from the backlight module to produce a frame by placing liquid crystal molecules in two parallel substrates, and by applying a driving voltage to the two substrates to control the orientations of the liquid crystal molecules.

In addition, in order to make the array substrate be capable of sensing the intensity of the external light to perform the self-regulations of the brightness and the contrast ratio, photosensors are provided on some array substrates. However, the difference between the photosensor and the switch element disables both of them from sharing a mask, thereby increasing the mask process, so that the production efficiency is not high.

It should be noted that the above-mentioned description of the technical background is merely for the purpose of facilitating the clear and complete descriptions of the technical solutions of this disclosure, and is provided for the understanding of those skilled in the art. The above-mentioned technical solutions are considered to be well known to those skilled in the art merely because these schemes are set forth in the background of this disclosure.

### SUMMARY

In view of the above-identified defects mentioned in the related art, the technical problem to be solved by this disclosure is to provide an array substrate, which is capable of saving the mask process and increasing the production efficiency, and a method of manufacturing the array substrate.

An objective of this disclosure is achieved by providing a method of manufacturing an array substrate, comprising: forming a gate metal layer on a substrate, and forming a gate insulating layer on the gate metal layer; forming an amorphous silicon layer, an N-type amorphous silicon layer and a source metal and a drain metal on the gate insulating layer and in correspondence with the gate metal layer, wherein the source metal and the drain metal are on a same layer; forming a metal layer to be a lower metal layer of a photosensor on an extension of the gate insulating layer; forming a light sensing layer, a passivation layer and a photoresist layer on the source metal, the drain metal and the metal layer; and forming a first light sensing layer and a first passivation layer on the source metal and the drain metal to form a switch element, and forming a second light sensing layer and a second passivation layer on the metal layer to form the photosensor by way of etching through a same halftone mask.

Optionally, the step of forming the first light sensing layer and the first passivation layer on the source metal and the drain metal, and forming the second light sensing layer and the second passivation layer on the metal layer by way of etching through the same halftone mask further comprises: etching through the same halftone mask to clean the light sensing layer and the passivation layer between the switch element and the photosensor to form the first light sensing layer and the first passivation layer on the source metal and the drain metal, and to form the second light sensing layer and the second passivation layer on the metal layer.

Optionally, the step of forming the first light sensing layer and the first passivation layer on the source metal and the drain metal to form the switch element, and forming the second light sensing layer and the second passivation layer on the metal layer to form the photosensor by way of etching through the same halftone mask further comprises: clearing the photoresist layer through a same process to form a first electrode layer on the first passivation layer, and to form a second electrode layer on the second passivation layer.

Optionally, the step of clearing the photoresist layer through the same process to form the first electrode layer on the first passivation layer, and to form the second electrode layer on the second passivation layer comprises: etching to form a groove penetrating through the first light sensing layer and extending to an upper surface of the drain metal on the first passivation layer corresponding to the drain metal; and forming the first electrode layer fully filled into the groove and extending to an upper surface of the first passivation layer.

Optionally, the step of clearing the photoresist layer through the same process to form the first electrode layer on the first passivation layer, and to form the second electrode layer on the second passivation layer comprises: etching the second passivation layer to form a first passivation block and a second passivation block, which are disposed on two ends of an upper surface of the second light sensing layer, and are separately and correspondingly disposed through a through slot; and forming the second electrode layer on the first passivation block, the second passivation block and the through slot.

Optionally, the step of clearing the photoresist layer through the same process to form the first electrode layer on the first passivation layer, and to form the second electrode layer on the second passivation layer comprises: etching to form a groove penetrating through the first light sensing layer and extending to an upper surface of the drain metal on the first passivation layer corresponding to the drain metal; while etching the second passivation layer to form a first passivation block and a second passivation block, which are disposed on two ends of an upper surface of the second light sensing layer, and are separately and correspondingly disposed through a through slot; and forming the first electrode layer fully filled into the groove and extending to an upper surface of the first passivation layer through the same process, while forming the second electrode layer on the first passivation block, the second passivation block and the through slot.

This disclosure also provides an array substrate, comprising: a substrate; a switch element disposed on the substrate; a photosensor disposed on the substrate and one side of the switch element; a first light sensing layer formed at the switch element; a second light sensing layer formed at the photosensor, wherein the second light sensing layer and the first light sensing layer are on a same layer; a first passivation layer is formed on the first light sensing layer; and a second passivation layer is formed on the second light sensing layer; the first passivation layer and the second passivation layer are on a same layer; the switch element comprises a source metal and a drain metal, wherein the first light sensing layer is formed on the source metal and the drain metal; the photosensor is formed on an extension of the gate insulating layer, the photosensor comprises a metal layer to be a lower metal layer formed on the extension of the gate insulating layer, and the second light sensing layer is formed on the metal layer; the first passivation layer is formed with a first electrode layer corresponding to the drain metal; the first passivation layer is provided with a groove corresponding to the drain metal, and the groove penetrates through the first light sensing layer from an upper surface of the first passivation layer, and extends to an upper surface of the drain metal; the first electrode layer is fully filled into the groove and extends to the upper surface of the first passivation layer; a second electrode layer is formed on the second passivation layer; the second passivation layer comprises a first passivation block and a second passivation block, which are disposed on two ends of an upper surface of the second light sensing layer, and are separately and correspondingly disposed through a through slot; and the second electrode layer is formed on the first passivation block, the second passivation block and the through slot.

This disclosure also provides an array substrate, comprising: a substrate; a switch element disposed on the substrate; a photosensor disposed on the substrate and one side of the switch element; and a second light sensing layer formed at the photosensor.

Optionally, the array substrate further comprises a first light sensing layer disposed at the switch element, wherein the first light sensing layer and the second light sensing layer are disposed on a same layer; a first passivation layer is formed on the first light sensing layer; and a second passivation layer is formed on the second light sensing layer; the first passivation layer and the second passivation layer are on a same layer; the switch element comprises a gate metal layer, a gate insulating layer is formed on the gate metal layer, an amorphous silicon layer and an N-type amorphous silicon layer are successively formed on the gate insulating layer, and a source metal and a drain metal disposed opposite each other are formed on the N-type amorphous silicon layer; and the first light sensing layer is formed on the source metal and the drain metal.

Optionally, the photosensor is formed on an extension of the gate insulating layer; and the photosensor comprises a metal layer to be a lower metal layer formed on the extension of the gate insulating layer, and the second light sensing layer is formed on the metal layer.

Optionally, the first passivation layer is formed with a first electrode layer corresponding to the drain metal.

Optionally, the first passivation layer is provided with a groove corresponding to the drain metal, and the groove penetrates through the first light sensing layer from an upper surface of the first passivation layer, and extends to an upper surface of the drain metal; and the first electrode layer is fully filled into the groove and extends to the upper surface of the first passivation layer.

Optionally, a second electrode layer is formed on the second passivation layer.

Optionally, the second passivation layer comprises a first passivation block and a second passivation block, which are disposed on two ends of an upper surface of the second light sensing layer, and are separately and correspondingly disposed through a through slot; and the second electrode layer is formed on the first passivation block, the second passivation block and the through slot.

Optionally, the first passivation layer is formed with a first electrode layer corresponding to the drain metal; and the first passivation layer is provided with a groove corresponding to the drain metal, and the groove penetrates through the first light sensing layer from an upper surface of the first passivation layer, and extends to an upper surface of the drain metal; and the first electrode layer is fully filled into the groove and extends to the upper surface of the first passivation layer; a second electrode layer is formed on the second passivation layer; the second passivation layer comprises a first passivation block and a second passivation block, which are disposed on two ends of an upper surface of the second light sensing layer, and are separately and correspondingly disposed through a through slot; and the second electrode layer is formed on the first passivation block, the second passivation block and the through slot; and the first electrode layer and the second electrode layer are on a same layer.

Optionally, a first electrode layer is formed on the first passivation layer, and a second electrode layer is formed on the second passivation layer; and the first electrode layer and the second electrode layer are on a same layer.

Optionally, the first passivation layer is provided with a groove corresponding to the drain metal, and the groove penetrates through the first light sensing layer from an upper surface of the first passivation layer, and extends to an upper surface of the drain metal; and the first electrode layer is fully filled into the groove and extends to the upper surface of the first passivation layer.

Optionally, the second passivation layer comprises a first passivation block and a second passivation block, which are disposed on two ends of an upper surface of the second light sensing layer, and are separately and correspondingly disposed through a through slot; and the second electrode layer is formed on the first passivation block, the second passivation block and the through slot.

Optionally, the first passivation layer is provided with a groove corresponding to the drain metal, and the groove penetrates through the first light sensing layer from an upper surface of the first passivation layer, and extends to an upper surface of the drain metal; the first electrode layer is fully filled into the groove and extends to the upper surface of the first passivation layer; the second passivation layer comprises a first passivation block and a second passivation block, which are disposed on two ends of an upper surface of the second light sensing layer, and are separately and correspondingly disposed through a through slot; and the second electrode layer is formed on the first passivation block, the second passivation block and the through slot.

Optionally, the array substrate further comprises a first light sensing layer disposed at the switch element, wherein the first light sensing layer and the second light sensing layer are disposed on a same layer; a first passivation layer is formed on the first light sensing layer; and a second passivation layer is formed on the second light sensing layer; the first passivation layer and the second passivation layer are on a same layer; the switch element comprises a gate metal layer, a gate insulating layer is formed on the gate metal layer, an amorphous silicon layer and an N-type amorphous silicon layer are successively formed on the gate insulating layer, and a source metal and a drain metal disposed opposite each other are formed on the N-type amorphous silicon layer; the first light sensing layer is formed on the source metal and the drain metal; the photosensor is formed on an extension of the gate insulating layer; the photosensor comprises a metal layer to be a lower metal layer formed on the extension of the gate insulating layer, and the second light sensing layer is formed on the metal layer; a first electrode layer and a second electrode layer formed on the second passivation layer are formed on the first passivation layer; and the first electrode layer and the second electrode layer are on a same layer.

In this disclosure, the photosensor is disposed beside the switch element, and the photosensor includes the second light sensing layer. Thus, the array substrate can sense the environment changes through the photosensor. More particularly, the intensity change of the external light can be sensed. Thus, when the light ray is strong, the display can automatically adjust to increase the brightness to prevent the too dark display frame from being seen. When the light ray is weak, the brightness is correspondingly darkened to prevent the too bright frame from harshening and hurting the eyes.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1 is a schematic view showing an array substrate of this disclosure;

FIG. 2 is a schematic view showing processes of manufacturing an array substrate of this disclosure; and

FIG. 3 is a flow chart showing a method of manufacturing an array substrate of this disclosure.

### DETAILED DESCRIPTION OF THE DISCLOSURE

The embodiments of the disclosure will be apparent from the following detailed description, which proceeds with reference to the accompanying drawings, wherein the same references relate to the same elements. Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

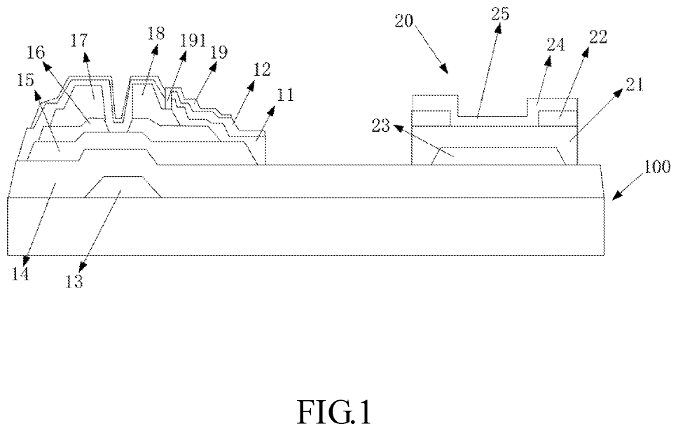

FIG. 1 shows an array substrate of this disclosure, comprising: a substrate 100; a switch element 10 disposed on the substrate 100; a photosensor 20 disposed on the substrate 100 and one side of the switch element 10; a second light sensing layer 21 formed at the photosensor 20.

In this disclosure, the photosensor is disposed beside the switch element, and the photosensor includes the second light sensing layer. Thus, the array substrate can sense the environment changes through the photosensor. More particularly, the intensity change of the external light can be sensed. Thus, when the light ray is strong, the display can automatically adjust to increase the brightness to prevent the too dark display frame from being seen. When the light ray is weak, the brightness is correspondingly darkened to prevent the too bright frame from harshening and hurting the eyes.

In this embodiment, optionally, the array substrate further comprises a first light sensing layer 11 disposed at the switch element 10, wherein the first light sensing layer 11 and the second light sensing layer 21 are disposed on a same layer; a first passivation layer 12 is formed on the first light sensing layer 11; and a second passivation layer 22 is formed on the second light sensing layer 21; the first passivation layer 12 and the second passivation layer 22 are on a same layer.

In this embodiment, the first light sensing layer and the second light sensing layer, included in the photosensor, are on a same layer. Thus, when the substrate process is being performed, both of them may be formed at a time, so that the mask usage and the process steps can be decreased to increase the production efficiency. In addition, the switch element includes the first passivation layer, and the photosensor includes the second passivation layer, wherein the first and second passivation layers are disposed on the same layer. Thus, the first passivation layer and the second passivation layer can be formed, through one mask process, thereby decreasing the process waste and increasing the production efficiency.

In this embodiment, optionally, the switch element 10 comprises a gate metal layer 13, a gate insulating layer 14 is formed on the gate metal layer 13, an amorphous silicon layer 15 and an N-type amorphous silicon layer 16 are successively formed on the gate insulating layer 14, and a source metal 17 and a drain metal 18 disposed opposite each other are formed on the N-type amorphous silicon layer 16; and the first light sensing layer 11 is formed on the source metal 17 and the drain metal 18.

In this embodiment, the other components of the switch element are described. The switch element is used to complete the control function of the substrate, and can perform the self-regulation according to the external environment sensing of the photosensor. With the backlight module, the brightness and contrast adjustment of the array substrate are finally completed, and the display effect is enhanced.

In this embodiment, optionally, the photosensor 20 is formed on an extension of the gate insulating layer 14; and the photosensor 20 comprises a metal layer 23 to be a lower metal layer formed on the extension of the gate insulating layer 14, and the second light sensing layer 21 is formed on the metal layer 23.

In this embodiment, the structure of the overall photosensor including the first light sensing layer is described. The photosensor is used to sense the external environment change, and more particularly, the light intensity change, thereby judging the intensity condition of the external light through the electrical signal sensing, thereby providing a reference to the control circuit, thus completing the brightness and contrast ratio regulations of the array substrate and enhancing the display effect. In addition, the metal layer serves as the lower electrode of the photosensor as well as the light-obstructing portion to prevent the backlight from irradiating into the second light sensing layer and prevent the misjudgement condition. The specific compositions of the first light sensing layer and the second light sensing layer are not the main application point of this disclosure, and detailed descriptions thereof will be omitted, as long as the light intensity detection can be completed.

In this embodiment, optionally, the first passivation layer 12 is formed with a first electrode layer 19 corresponding to the drain metal 18.

The first passivation layer 12 is provided with a groove 191 corresponding to the drain metal 18, and the groove 191 penetrates through the first light sensing layer 11 from an upper surface of the first passivation layer 12, and extends to an upper surface of the drain metal 18; and the first electrode layer 19 is fully filled into the groove 191 and extends to the upper surface of the first passivation layer 12.

In this embodiment, the first passivation layer is formed with a groove, which penetrates through the first light sensing layer and extends to an upper surface of the drain metal. Thus, the first electrode layer keeps its original function unchanged. Because the first electrode layer is connected to the drain metal, the first sensing layer, the drain metal and the first electrode layer cannot form the photosensor function, and the too-many functions, affecting the original function of the switch element, may be avoided.

In this embodiment, optionally, a second electrode layer 24 is formed on the second passivation layer 22.

The second passivation layer 22 comprises a first passivation block and a second passivation block, which are disposed on two ends of an upper surface of the second light sensing layer 21, and are separately and correspondingly disposed through a through slot 25; and the second electrode layer 24 is formed on the first passivation block, the second passivation block and the through slot 25.

In this embodiment, the function implementation of the photosensor includes the second light sensing layer, the second electrode layer and the metal layer. By sensing the electrical signal changes of the second electrode layer and the light sensing layer, it is possible to judge the light change of the external environment, thereby completing the brightness and contrast ratio regulations of the array substrate.

In this embodiment, optionally, a first electrode layer 19 is formed on the first passivation layer 12, and a second electrode layer 24 is formed on the second passivation layer 22; and the first electrode layer 19 and the second electrode layer 24 are on a same layer.

In this embodiment, the first electrode layer and the second electrode layer are on the same layer, that is, the first electrode layer and the second electrode layer can be formed through a single process, thereby reducing the waste of the process and improving the production efficiency.

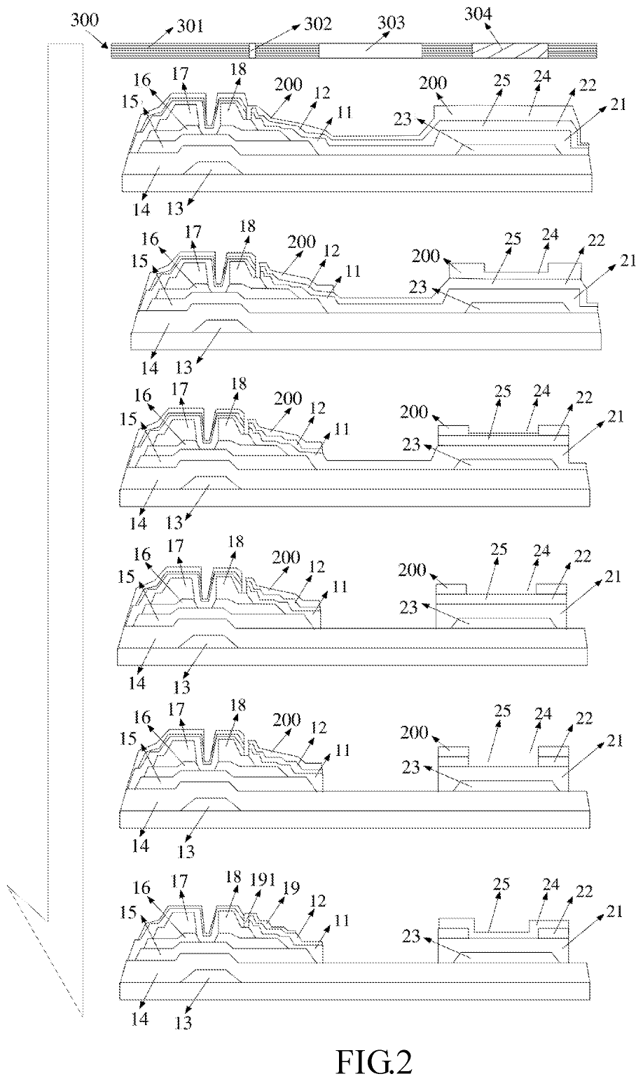

In FIG. 2, the second halftone mask 300 and the photoresist 200 play an important role; wherein the obstructing portion 301 prevents the location which needs not to be etched from being etched. The first portion 302 is used to etch the groove 191. The second portion 303 is used to etch the spacer portion between the switch element 10 and the photosensor 20. The third portion 304 is used to etch the through slot 25. The third portion 304, the first portion 302 and the second portion 303 have different transmission rates, thereby implementing different etch levels at the through slot 25 and other portions.

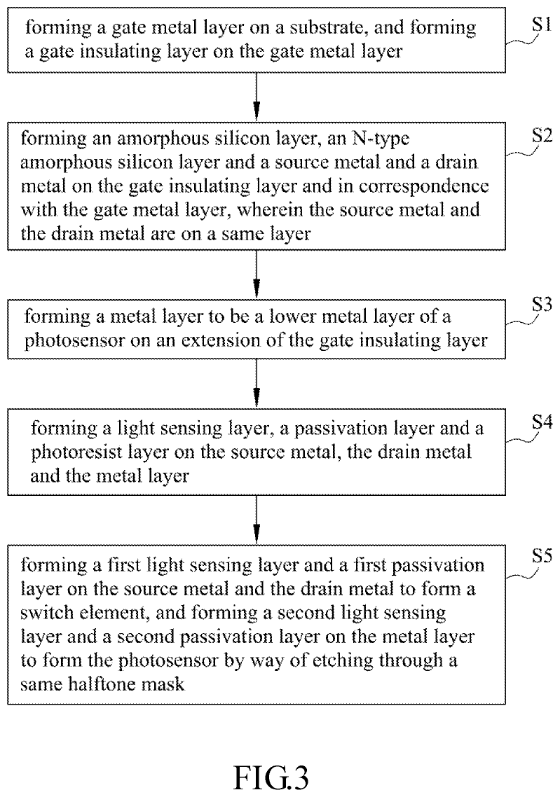

FIG. 3 is a flow chart showing a method of manufacturing an array substrate of this disclosure. The method comprises:

S1: forming a gate metal layer 13 on a substrate, and forming a gate insulating layer 14 on the gate metal layer 13;

S2: forming an amorphous silicon layer, an N-type amorphous silicon layer and a source metal 17 and a drain metal 18 on the gate insulating layer 14 and in correspondence with the gate metal layer 13, wherein the source metal and the drain metal are on a same layer;

S3: forming a metal layer 23 to be a lower metal layer of a photosensor on an extension of the gate insulating layer 14;

S4: forming a light sensing layer, a passivation layer and a photoresist layer on the source metal 17, the drain metal 18 and the metal layer 23;

S5: forming a first light sensing layer 11 and a first passivation layer 12 on the source metal 17 and the drain metal 18 to form a switch element 10, and forming a second light sensing layer 21 and a second passivation layer 22 on the metal layer 23 to form the photosensor 20 by way of etching through a same halftone mask 300.

In the method of manufacturing the array substrate of this disclosure, the switch element comprises a first light sensing layer, and the photosensor comprises a second light sensing layer, wherein the first light sensing layer and the second light sensing layer are on the same layer. Thus, when the substrate process is being performed, both of them may be formed at a time, so that the mask usage and the process steps can be decreased to increase the production efficiency. In addition, the photosensor is disposed beside the switch element. Thus, the array substrate can sense the environment changes through the photosensor. More particularly, the intensity change of the external light can be sensed. Thus, when the light ray is strong, the display can automatically adjust to increase the brightness to prevent the too dark display frame from being seen. When the light ray is weak, the brightness is correspondingly darkened to prevent the too bright frame from harshening and hurting the eyes.

In this embodiment, optionally, the step of forming the first light sensing layer 11 and the first passivation layer 12 on the source metal 17 and the drain metal 18, and forming the second light sensing layer 21 and the second passivation layer 22 on the metal layer 23 by way of etching through the same halftone mask 30 further comprises: etching through the same halftone mask 300 to clean the light sensing layer and the passivation layer between the switch element 10 and the photosensor 20 to form the first light sensing layer 11 and the first passivation layer 12 on the source metal 17 and the drain metal 18, and to form the second light sensing layer 21 and the second passivation layer 22 on the metal layer 23.

Etching the first passivation layer 12 corresponding to the drain metal 18 to form a groove 191, which penetrates through the first light sensing layer 11 and extends to the upper surface of the drain metal 18, through the same process. Meanwhile, the second passivation layer 22 is etched to form a first passivation block and a second passivation block, which are disposed on two ends of the upper surface of the second light sensing layer 21, and are separately and correspondingly disposed through a through slot 25.

Clearing the photoresist layer 200 through a same process to form a first electrode layer 19 on the first passivation layer 12, and to form a second electrode layer 24 on the second passivation layer 22.

In this embodiment, the first passivation layer is formed with a groove, which penetrates through the first light sensing layer and extends to an upper surface of the drain metal. Thus, the first electrode layer keeps its original function unchanged. Because the first electrode layer is connected to the drain metal, the first sensing layer, the drain metal and the first electrode layer cannot form the photosensor function, and the too-many functions, affecting the original function of the switch element, may be avoided. In addition, the function implementation of the photosensor includes the second light sensing layer, the second electrode layer and the metal layer. By sensing the electrical signal changes of the second electrode layer and the light sensing layer, it is possible to judge the light change of the external environment, thereby completing the brightness and contrast ratio regulations of the array substrate. The metal layer serves as the lower electrode of the photosensor as well as the light-obstructing portion to prevent the backlight from irradiating into the second light sensing layer and prevent the misjudgement condition. The specific compositions of the first light sensing layer and the second light sensing layer are not the main application point of this disclosure, and detailed descriptions thereof will be omitted, as long as the light intensity detection can be completed. In addition, regarding the halftone mask of this disclosure, when the light sensing layer, the passivation layer, the groove and the through slot are etched, the location corresponding to the through slot, the semi-permeable membrane there and the semi-permeable membrane at other hollow portions have different transmission rates, thereby implementing the difference between the etch levels of the through slot and other locations. The implementation of the difference makes the formation at the above-mentioned locations using one mask process become feasible, thereby increasing the production efficiency.

In this embodiment, optionally, the first electrode layer 19 is fully filled into the groove 191 and extends to the upper surface of the first passivation layer 12; the second electrode layer 24 is formed on the first passivation block, the second passivation block and the through slot 25; the first electrode layer 19 and the second electrode layer 24 are on the same layer.

In this embodiment, the first electrode layer and the second electrode layer are on the same layer, that is, the first electrode layer and the second electrode layer can be formed through a single process, thereby reducing the waste of the process and improving the production efficiency.

In the above embodiment, the array substrate includes a liquid crystal display, an organic light-emitting diode (OLED) display, a quantum dot light emitting diodes (QLED) display, a plasma display, a flat type display, a curved display and the like.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. A method of manufacturing an array substrate, comprising:
forming a gate metal layer on a substrate, and forming a gate insulating layer on the gate metal layer;
forming an amorphous silicon layer, an N-type amorphous silicon layer and a source metal and a drain metal on the gate insulating layer and in correspondence with the gate metal layer, wherein the source metal and the drain metal are on a same layer;
forming a metal layer to be a lower metal layer of a photosensor on an extension of the gate insulating layer;
forming a light sensing layer, a passivation layer and a photoresist layer on the source metal, the drain metal and the metal layer; and
forming a first light sensing layer and a first passivation layer on the source metal and the drain metal to form a switch element, and forming a second light sensing layer and a second passivation layer on the metal layer to form the photosensor by way of etching through a same halftone mask.

2. The method of manufacturing the array substrate according to claim 1, wherein the step of forming the first light sensing layer and the first passivation layer on the source metal and the drain metal, and forming the second light sensing layer and the second passivation layer on the metal layer by way of etching through the same halftone mask further comprises:
etching through the same halftone mask to clean the light sensing layer and the passivation layer between the switch element and the photosensor to form the first light sensing layer and the first passivation layer on the source metal and the drain metal, and to form the second light sensing layer and the second passivation layer on the metal layer.

3. The method of manufacturing the array substrate according to claim 2, wherein the step of forming the first light sensing layer and the first passivation layer on the source metal and the drain metal to form the switch element, and forming the second light sensing layer and the second passivation layer on the metal layer to form the photosensor by way of etching through the same halftone mask further comprises:
clearing the photoresist layer through a same process to form a first electrode layer on the first passivation layer, and to form a second electrode layer on the second passivation layer.

4. The method of manufacturing the array substrate according to claim 3, wherein the step of clearing the photoresist layer through the same process to form the first electrode layer on the first passivation layer, and to form the second electrode layer on the second passivation layer comprises:
etching to form a groove penetrating through the first light sensing layer and extending to an upper surface of the drain metal on the first passivation layer corresponding to the drain metal; and
forming the first electrode layer fully filled into the groove and extending to an upper surface of the first passivation layer.

5. The method of manufacturing the array substrate according to claim 3, wherein the step of clearing the photoresist layer through the same process to form the first electrode layer on the first passivation layer, and to form the second electrode layer on the second passivation layer comprises:
etching the second passivation layer to form a first passivation block and a second passivation block, which are disposed on two ends of an upper surface of the second light sensing layer, and are separately and correspondingly disposed through a through slot; and
forming the second electrode layer on the first passivation block, the second passivation block and the through slot.

6. The method of manufacturing the array substrate according to claim 3, wherein the step of clearing the photoresist layer through the same process to form the first electrode layer on the first passivation layer, and to form the second electrode layer on the second passivation layer comprises:
etching to form a groove penetrating through the first light sensing layer and extending to an upper surface of the drain metal on the first passivation layer corresponding to the drain metal; while etching the second passivation layer to form a first passivation block and a second passivation block, which are disposed on two ends of an upper surface of the second light sensing layer, and are separately and correspondingly disposed through a through slot; and
forming the first electrode layer fully filled into the groove and extending to an upper surface of the first passivation layer through the same process, while forming the second electrode layer on the first passivation block, the second passivation block and the through slot.

7. An array substrate, comprising:
a substrate;
a switch element disposed on the substrate;
a photosensor disposed on the substrate and one side of the switch element;
a first light sensing layer formed at the switch element;
a second light sensing layer formed at the photosensor, wherein the second light sensing layer and the first light sensing layer are on a same layer;
a first passivation layer is formed on the first light sensing layer; and a second passivation layer is formed on the second light sensing layer;
the first passivation layer and the second passivation layer are on a same layer;
the switch element comprises a source metal and a drain metal, wherein the first light sensing layer is formed on the source metal and the drain metal;
the photosensor is formed on an extension of the gate insulating layer, the photosensor comprises a metal layer to be a lower metal layer formed on the extension of the gate insulating layer, and the second light sensing layer is formed on the metal layer;
the first passivation layer is formed with a first electrode layer corresponding to the drain metal;
the first passivation layer is provided with a groove corresponding to the drain metal, and the groove penetrates through the first light sensing layer from an upper surface of the first passivation layer, and extends to an upper surface of the drain metal;
the first electrode layer is fully filled into the groove and extends to the upper surface of the first passivation layer;
a second electrode layer is formed on the second passivation layer;
the second passivation layer comprises a first passivation block and a second passivation block, which are disposed on two ends of an upper surface of the second light sensing layer, and are separately and correspondingly disposed through a through slot; and
the second electrode layer is formed on the first passivation block, the second passivation block and the through slot.

8. An array substrate, comprising:
a substrate;
a switch element disposed on the substrate;
a photosensor disposed on the substrate and one side of the switch element; and
a second light sensing layer formed at the photosensor.

9. The array substrate according to claim 8, wherein:
the array substrate further comprises a first light sensing layer disposed at the switch element, wherein the first light sensing layer and the second light sensing layer are disposed on a same layer;
a first passivation layer is formed on the first light sensing layer; and a second passivation layer is formed on the second light sensing layer;
the first passivation layer and the second passivation layer are on a same layer;
the switch element comprises a gate metal layer, a gate insulating layer is formed on the gate metal layer, an amorphous silicon layer and an N-type amorphous silicon layer are successively formed on the gate insulating layer, and a source metal and a drain metal disposed opposite each other are formed on the N-type amorphous silicon layer; and
the first light sensing layer is formed on the source metal and the drain metal.

10. The array substrate according to claim 9, wherein the photosensor is formed on an extension of the gate insulating layer; and
the photosensor comprises a metal layer to be a lower metal layer formed on the extension of the gate insulating layer, and the second light sensing layer is formed on the metal layer.

11. The array substrate according to claim 9, wherein the first passivation layer is formed with a first electrode layer corresponding to the drain metal.

12. The array substrate according to claim 11, wherein the first passivation layer is provided with a groove corresponding to the drain metal, and the groove penetrates through the first light sensing layer from an upper surface of the first passivation layer, and extends to an upper surface of the drain metal; and
the first electrode layer is fully filled into the groove and extends to the upper surface of the first passivation layer.

13. The array substrate according to claim 10, wherein a second electrode layer is formed on the second passivation layer.

14. The array substrate according to claim 13, wherein the second passivation layer comprises a first passivation block and a second passivation block, which are disposed on two ends of an upper surface of the second light sensing layer, and are separately and correspondingly disposed through a through slot; and
the second electrode layer is formed on the first passivation block, the second passivation block and the through slot.

15. The array substrate according to claim 9, wherein the first passivation layer is formed with a first electrode layer corresponding to the drain metal; and
the first passivation layer is provided with a groove corresponding to the drain metal, and the groove penetrates through the first light sensing layer from an upper surface of the first passivation layer, and extends to an upper surface of the drain metal; and the first electrode layer is fully filled into the groove and extends to the upper surface of the first passivation layer;
a second electrode layer is formed on the second passivation layer;
the second passivation layer comprises a first passivation block and a second passivation block, which are disposed on two ends of an upper surface of the second light sensing layer, and are separately and correspondingly disposed through a through slot; and the second electrode layer is formed on the first passivation block, the second passivation block and the through slot; and
the first electrode layer and the second electrode layer are on a same layer.

16. The array substrate according to claim 9, wherein a first electrode layer is formed on the first passivation layer, and a second electrode layer is formed on the second passivation layer; and
the first electrode layer and the second electrode layer are on a same layer.

17. The array substrate according to claim 16, wherein the first passivation layer is provided with a groove corresponding to the drain metal, and the groove penetrates through the first light sensing layer from an upper surface of the first passivation layer, and extends to an upper surface of the drain metal; and the first electrode layer is fully filled into the groove and extends to the upper surface of the first passivation layer.

18. The array substrate according to claim 16, wherein the second passivation layer comprises a first passivation block and a second passivation block, which are disposed on two ends of an upper surface of the second light sensing layer, and are separately and correspondingly disposed through a through slot; and the second electrode layer is formed on the first passivation block, the second passivation block and the through slot.

19. The array substrate according to claim 16, wherein the first passivation layer is provided with a groove corresponding to the drain metal, and the groove penetrates through the first light sensing layer from an upper surface of the first passivation layer, and extends to an upper surface of the drain metal; the first electrode layer is fully filled into the groove and extends to the upper surface of the first passivation layer;
the second passivation layer comprises a first passivation block and a second passivation block, which are disposed on two ends of an upper surface of the second light sensing layer, and are separately and correspondingly disposed through a through slot; and the second electrode layer is formed on the first passivation block, the second passivation block and the through slot.

20. The array substrate according to claim 8, wherein:
the array substrate further comprises a first light sensing layer disposed at the switch element, wherein the first light sensing layer and the second light sensing layer are disposed on a same layer;
a first passivation layer is formed on the first light sensing layer; and a second passivation layer is formed on the second light sensing layer;
the first passivation layer and the second passivation layer are on a same layer;
the switch element comprises a gate metal layer, a gate insulating layer is formed on the gate metal layer, an amorphous silicon layer and an N-type amorphous silicon layer are successively formed on the gate insulating layer, and a source metal and a drain metal disposed opposite each other are formed on the N-type amorphous silicon layer;
the first light sensing layer is formed on the source metal and the drain metal;
the photosensor is formed on an extension of the gate insulating layer;
the photosensor comprises a metal layer to be a lower metal layer formed on the extension of the gate insulating layer, and the second light sensing layer is formed on the metal layer;
a first electrode layer and a second electrode layer formed on the second passivation layer are formed on the first passivation layer; and
the first electrode layer and the second electrode layer are on a same layer.
